(19) United States
(12) Patent Application Publication
(10) Pub. No.: US 2013/0337636 A1
(43) Pub. Date: Dec. 19, 2013

(54) CARBON DOPING OF GALLIUM ARSENIDE VIA HYDRIDE VAPOR PHASE EPITAXY

(71) Applicants: Thomas Kuech, Madison, WI (US); Kevin Schulte, Madison, WI (US)

(72) Inventors: Thomas Kuech, Madison, WI (US); Kevin Schulte, Madison, WI (US)

(21) Appl. No.: 13/523,134

(22) Filed: Jun. 14, 2012

(51) Int. Cl. H01L 21/20

(52) U.S. Cl. 438/478; 257/E21.09

(57) ABSTRACT

Methods for growing layers of carbon doped GaAs are provided. Methods include exposing a substrate to a gas mixture comprising a source of Ga, a source of As and a dopant comprising a haloalkane under conditions sufficient to grow a layer of carbon doped GaAs on the substrate via hydride vapor phase epitaxy. The haloalkane can include a bromoalkane, a bromochloroalkane, an iodoalkane or combinations thereof. The concentration of carbon in the layer can be 1×10¹⁵ cm⁻³ or greater.

### REFERENCE TO GOVERNMENT RIGHTS

This invention was made with government support under XEJ-0-99047-01 awarded by the Department of Energy. The government has certain rights in the invention.

### BACKGROUND

Incorporation of carbon into gallium arsenide (GaAs) is of interest for a number of applications. Carbon is a particularly attractive acceptor species at least because of its high solubility, low diffusion coefficient and low acceptor binding energy compared to conventional Zn and Mg acceptors. Attempts at doping GaAs with carbon using Ga:AsCl₃:H₂ or N₂ vapor phase epitaxy have been largely unsuccessful, achieving only negligible doping levels. More recent methods for doping GaAs with carbon have focused on the use of metal-organic vapor phase epitaxy (MOVPE). By contrast to the earlier vapor phase epitaxy attempts, MOVPE has achieved high doping levels and offers the advantages of high crystalline quality and excellent control over composition and thickness.

### SUMMARY

Provided herein are methods for growing layers of carbon doped GaAs.

In one embodiment, a method of growing carbon doped GaAs comprises exposing a substrate to a gas mixture comprising a source of Ga, a source of As and a dopant comprising a haloalkane under conditions sufficient to grow a layer of carbon doped GaAs on the substrate via hydride vapor phase epitaxy.

In one embodiment, a method of growing carbon doped GaAs comprises exposing a substrate to a gas mixture comprising a source of Ga, a source of As and a dopant comprising a haloalkane under conditions sufficient to grow a layer of carbon doped GaAs on the substrate via hydride vapor phase epitaxy, wherein the haloalkane comprises a bromoalkane, a bromochloroalkane, an iodoalkane or combinations thereof

In one embodiment, a method of growing carbon doped GaAs comprises exposing a substrate to a gas mixture comprising a source of Ga, a source of As and a dopant comprising a haloalkane under conditions sufficient to grow a layer of carbon doped GaAs on the substrate via hydride vapor phase epitaxy, wherein the concentration of carbon in the layer is about 1×10¹⁵ cm⁻³ or greater.

Layers formed using the disclosed methods will find use in a variety of device applications, such as pn junctions for photovoltaic cells, heterojunction bipolar transistors and semiconductor laser diodes.

Other principal features and advantages of the invention will become apparent to those skilled in the art upon review of the following drawings, the detailed description, the examples and the appended claims.

### BRIEF DESCRIPTION OF THE DRAWINGS

Illustrative embodiments of the invention will hereafter be described with reference to the accompanying drawings.

FIG. 1 depicts an illustrative reactor for hydride vapor phase epitaxy (HVPE) that can be used to carry out the disclosed methods.

FIGS. 2A-C show plots of dopant concentration as a function of depth for three samples, A-C, of layers of carbon doped GaAs formed in accordance with an illustrative embodiment of the disclosed methods.

### DETAILED DESCRIPTION

Provided herein are methods for growing layers of carbon doped GaAs. The methods are based on hydride vapor phase epitaxy (HVPE). Compared to previous attempts at carbon doping using Ga:AsCl₃:H₂ or N₂ vapor phase epitaxy, at least certain embodiments of the methods are capable of achieving significantly higher dopant concentrations (e.g., ˜1×10¹⁵ cm⁻³ or greater). Compared to MOVPE based methods, at least certain embodiments of the methods are capable of providing significantly higher growth rates (e.g., ˜200 μm/hr or greater), thereby providing increased throughput.

In one embodiment, a method includes exposing a substrate to a gas mixture, the gas mixture comprising a source of Ga, a source of As, and a dopant comprising a haloalkane, under conditions sufficient to grow a layer of carbon doped GaAs on the substrate via hydride vapor phase epitaxy (HVPE).

A variety of haloalkanes may be used in the methods. Haloalkanes are alkanes in which one or more hydrogen atoms are replaced by one or more halogen atoms. Straight, branched and cyclic haloalkanes may be used. Haloalkanes having various numbers of carbon atoms may be used. In some embodiments, the haloalkane includes at least 1, but no more than 6 carbon atoms. This includes embodiments in which the haloalkane includes at least 1, but no more than 3 carbon atoms and further includes embodiments in which the haloalkane includes at least 1, but no more than 2 carbon atoms. A variety of halogens may be used, including bromine, chlorine and iodine. Haloalkanes having two or more different halogens may be used, e.g., bromine and chlorine.

In some embodiments, the haloalkanes comprise bromoalkanes. In some embodiments, the bromoalkane comprises CBr₄, CHBr₃, CH₂Br₂, or CH₃Br. In some embodiments, the haloalkanes comprise chloroalkanes. In some embodiments, the chloroalkane comprises CCl₄, CHCl₃, CH₂Cl₂, or CH₃Cl. In some embodiments, the haloalkanes comprise iodoalkanes. In some embodiments, the iodoalkane comprises Cl₄, CHI₃, CH₂I₂, or CH₃I. In some embodiments, the haloalkanes comprise bromochloroalkanes. In some embodiments, the bromochloroalkane comprises CBrCl₃, CBr₂Cl₂, CBr₃Cl, CHBrCl₂, CHBr₂Cl, or CH₂BrCl.

Combinations of two or more different haloalkanes may be used. In some embodiments, the dopant does not comprise CCl₄. In some embodiments, the dopant consists of any of the haloalkanes described above.

As noted above, in one embodiment, the carbon doped GaAs layer is grown via HVPE. In such embodiments, the source of Ga may be GaCl, which may be provided by reacting gaseous HCl with liquid Ga. The source of As may be gaseous AsH₃ or elemental arsenic. An exemplary reactor and exemplary process conditions for carrying out HVPE are described in the Examples below. These process conditions include the flow rates of gases into the reactor (e.g., the flow rate of gaseous HCl to the liquid Ga), the growth temperature, the growth time, etc. These process conditions may be adjusted to maximize the dopant concentration in the layer of GaAs. As an illustrative example, the total flow rate of the gases into the reactor may be 3000 standard cubic centimeters per minute (sccm), with 11 sccm GaCl, 26 sccm AsH₃ and the balance H₂. As an illustrative example, the growth temperature may be in the range from 600° C. to 800° C. or from 700° C. to 750° C.

A variety of substrates may be used for growing the carbon doped GaAs layers. An exemplary substrate is GaAs, which may be doped or undoped.

The carbon doped GaAs layers grown using the disclosed methods may be characterized by their dopant concentrations. In some embodiments, the concentration of carbon in the layer is about 1×10¹⁵ cm⁻³ or greater. In some embodiments, the concentration of carbon in the layer is about 5×10¹⁵ cm⁻³ or greater. In some embodiments, the concentration of carbon in the layer is about 1×10¹⁶ cm⁻³ or greater. In some embodiments, the concentration of carbon in the layer is about 5×10¹⁶ cm⁻³ or greater. In some embodiments, the concentration of carbon in the layer is about 1×10¹⁷ cm⁻³ or greater. In some embodiments, the concentration of carbon in the layer is about 5×10¹⁷ cm⁻³ or greater.

Hydride vapor phase epitaxy may be used to dope other group III-V material layers (besides GaAs) with carbon. Other material layers include those in the InGaAsP system including InP, GaP, InGaAs, InGaP and GaAsP. In one embodiment, a method includes exposing a substrate to a gas mixture comprising a source of the group III element(s), a source of the group V element(s) and a dopant comprising a haloalkane under conditions sufficient to grow a layer of the carbon doped group III-V material on the substrate via HVPE. Sources for the group III elements and the group V elements are known. Any of the haloalkanes disclosed above may be used. The reactor and process conditions described above may be used to achieve carbon concentrations similar to those disclosed above.

The methods and carbon doped GaAs layers will be understood more readily by reference to the following examples, which are provided by way of illustration and are not intended to be limiting.

### Examples

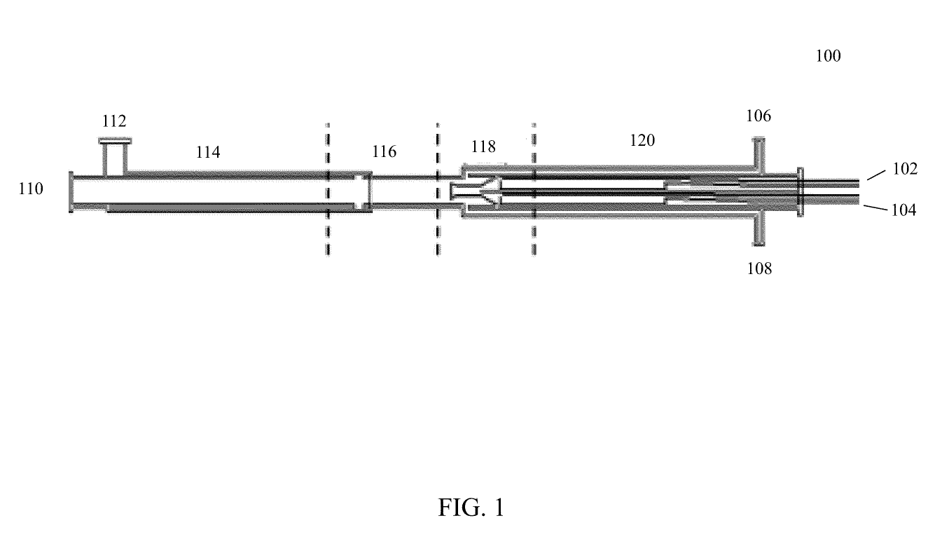

A custom built HVPE reactor was used to grow layers of carbon doped GaAs. Details of the HVPE reactor and its operation may be found in K. L. Schulte, et al., Journal of Crystal Growth (2011), doi:10.1016/j.jcrysgro.2011.11.013, which is hereby incorporated by reference in its entirety. Briefly, as shown in FIG. 1, the reactor 100 features five inlet ports 102-110 and an exhaust outlet 112. The reaction tube is enclosed in a 4-zone clamshell resistance furnace, which allows independent control of the temperatures in the preheat 114, deposition 116, mixing 118 and source 120 zones. To carry out the growth of the carbon doped GaAs, gaseous HCl in a H₂ carrier was introduced through ports 102 or 104 where it reacted with liquid Ga contained within a quartz boat resulting in the formation of GaCl, which served as the group III transport agent. The boat served to isolate the metal source from the reaction environment to reduce cross-contamination. The group V gas, AsH₃, entered through port 106 and the dopant was passed through port 108, both carried by H₂. The H₂ flow was adjusted such that the total flow (hydride+carrier+dopant) through both ports was kept constant. The gases were kept separate until merging at the mixing zone 118. This mixing zone was kept at a higher temperature than the rest of the system, which served to prevent premature deposition. The GaCl passed through a nozzle to promote mixing in the reactant stream. A key feature of the reactor is the centrally located exhaust, which forces gases into an interstitial space in the quartz barrel and routes them outside of the furnace to the outlet 112. This feature allows a growth interruption mechanism to be utilized (if desired) to prevent transient growth.

A typical growth procedure was as follows: a horizontally-oriented substrate was moved into the preheat zone 114 by a quartz transfer arm and allowed to equilibrate at the growth temperature under a protective stream of H₂/AsH₃ that was injected through port 110. Simultaneously, the desired gases were introduced through ports 102-108. This flow was allowed to equilibrate for 5-10 min while heating the substrate. This transient flow did not reach the substrate within the preheat position, which was protected by the counter flow of H₂/AsH₃ flow (port 110), which exited through the central exhaust. After this startup period, the substrate was moved into the deposition zone 116 to initiate growth.

If desired, in order to grow additional layers of a new composition over already grown layers, the sample may be retracted into the protective H₂/AsH₃ flow within the preheat zone 114, a new gas mixture allowed to equilibrate within the reactor and the sample once again moved to the growth position. The process may be repeated as desired.

Three samples of layers of carbon doped GaAs were grown using the HVPE reactor and process described above. Each sample was grown on a p⁺ GaAs substrate doped with zinc; the substrate was oriented in the 001 direction with a 4° miscut towards the [111]B direction. The dopant was CBrCl₃. Process conditions for each sample are shown in Table 1 below.

TABLE 1
Process Conditions for Carbon Doped GaAs Samples

| | | | Q H₂ | Q H₂ | | Deposition |
|---|---|---|---|---|---|---|
| Sample | Q GaCl | Q AsH₃ | (bubbler) | (carrier) | Bubbler T | T |
| A | 6 | 30 | 50 | 1500 | 15 | 700 |
| B | 6 | 30 | 25 | 1500 | 0 | 700 |
| C | 6 | 48 | 10 | 1500 | −4 | 700 |

Flow rates (Q) are given in standard cubic centimeters per minute (sccm). Temperatures (T) are given in ° C. Q GaCl is the flow rate of HCl to the liquid gallium source. Q AsH₃ is the flow rate of AsH₃. Q H₂ (bubbler) is the flow of hydrogen to the bubbler containing the CBrCl₃ dopant. Q H2 (carrier) is the flow rate of the hydrogen carrier gas. Bubbler T is the temperature of the CBrCl₃ bubbler. Deposition T is the growth temperature, i.e., the temperature of the deposition zone 116. The temperatures of the preheat 114, mixing 118, and source 120 zones were 700° C., 780° C., and 775° C., respectively. High purity H₂, HCl and AsH₃ were utilized, along with a six-nines pure gallium source. The purity of the CBrCl₃ was 99.995%. All gas streams were purified to remove oxygen, water and other impurities.

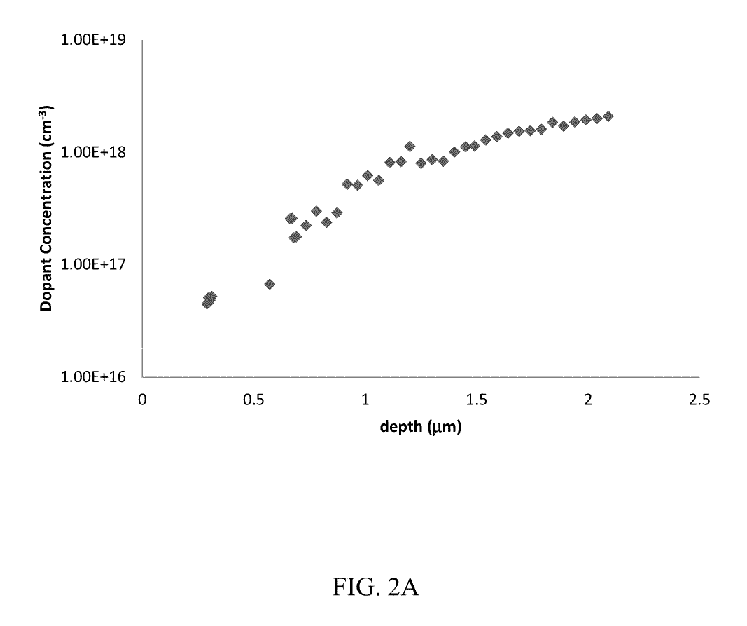

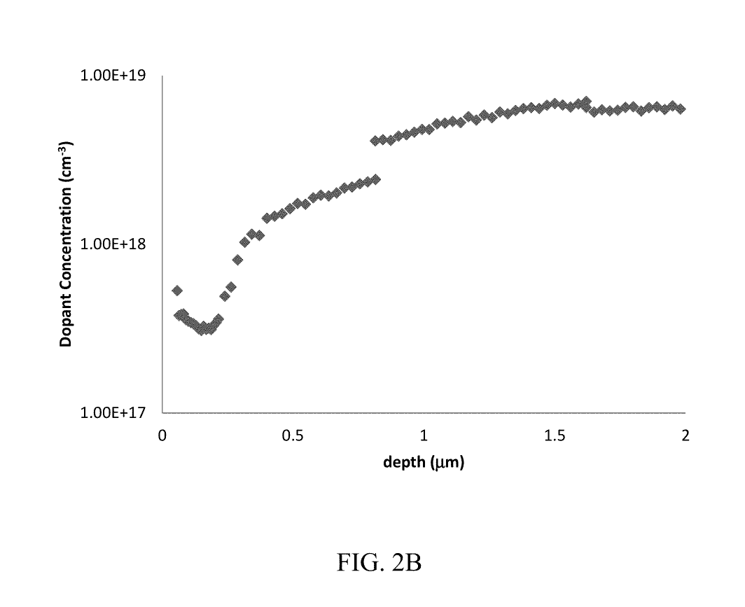

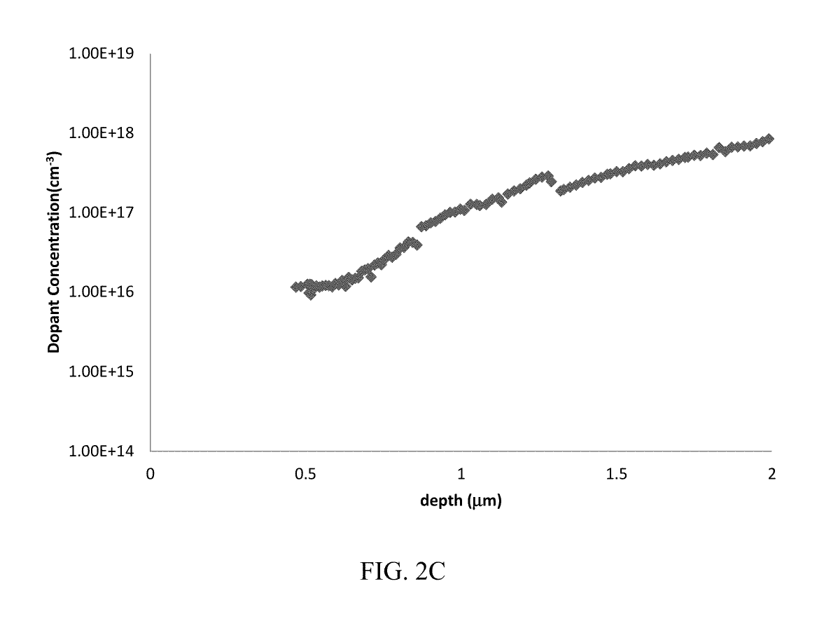

The dopant concentration in the samples was analyzed by electrochemical capacitance voltage profiling. Plots of the dopant concentration as a function of depth for samples A-C are shown in FIGS. 2A-C, respectively. The dopant concentration in the GaAs layers is given by the data points closest to the surface of the sample. Thus, the dopant concentrations in samples A-C were as follows: ˜5×10¹⁶ cm⁻³ (A); ˜7×10¹⁷ cm⁻³ (B); and ˜1×10¹⁶ cm⁻³ (C). The dopant concentration in the underlying p⁺ GaAs substrates is given by the data points at greater depths and was on the order of 1×10¹⁸ cm⁻³.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”. Still further, the use of “and” or “or” is intended to include “and/or” unless specifically indicated otherwise.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of growing carbon doped GaAs, the method comprising:
exposing a substrate to a gas mixture comprising a source of Ga, a source of As and a dopant comprising a haloalkane under conditions sufficient to grow a layer of carbon doped GaAs on the substrate via hydride vapor phase epitaxy, wherein the haloalkane comprises a bromoalkane, a bromochloroalkane, an iodoalkane or combinations thereof

2. The method of claim 1, wherein the haloalkane comprises a bromochloroalkane.

3. The method of claim 1, wherein the haloalkane comprises CBrCl₃, CBr₂Cl₂, CBr₃Cl, CHBrCl₂, CHBr₂Cl, CH₂BrCl or combinations thereof.

4. The method of claim 1, wherein the haloalkane comprises CBrCl₃.

5. The method of claim 1, wherein the haloalkane comprises a bromoalkane.

6. The method of claim 1, wherein the haloalkane comprises CBr₄, CHBr₃, CH₂Br₂, CH₃Br or combinations thereof.

7. The method of claim 1, wherein the haloalkane comprises an iodoalkane.

8. The method of claim 1, wherein the haloalkane comprises CI₄, CHI₃, CH₂I₂, CH₃I or combinations thereof.

9. The method of claim 1, wherein the source of As is AsH₃ or As.

10. The method of claim 1, wherein the concentration of carbon in the layer is about 1×10¹⁵ cm⁻³ or greater.

11. The method of claim 1, wherein the concentration of carbon in the layer is about 1×10¹⁶ cm⁻³ or greater.

12. A method of growing carbon doped GaAs, the method comprising:
exposing a substrate to a gas mixture comprising a source of Ga, a source of As and a dopant comprising a haloalkane under conditions sufficient to grow a layer of carbon doped GaAs on the substrate via hydride vapor phase epitaxy, wherein the concentration of carbon in the layer is about 1×10¹⁵ cm⁻³ or greater.

13. The method of claim 12, wherein the concentration of carbon in the layer is about 1×10¹⁶ cm⁻³ or greater.

14. The method of claim 12, wherein the haloalkane comprises a bromochloroalkane.

15. The method of claim 12, wherein the haloalkane comprises CBrCl₃, CBr₂Cl₂, CBr₃Cl, CHBrCl₂, CHBr₂Cl, CH₂BrCl or combinations thereof.

16. The method of claim 12, wherein the haloalkane comprises CBrCl₃.

17. The method of claim 12, wherein the haloalkane comprises a bromoalkane.

18. The method of claim 12, wherein the haloalkane comprises CBr₄, CHBr₃, CH₂Br₂, CH₃Br or combinations thereof.

19. The method of claim 12, wherein the haloalkane comprises an iodoalkane.

20. The method of claim 12, wherein the haloalkane comprises CI₄, CHI₃, CH₂I₂, CH₃I or combinations thereof.
